(19) United States
(12) Patent Application Publication
(10) Pub. No.: US 2025/0020725 A1
(43) Pub. Date: Jan. 16, 2025

(54) METHOD AND APPARATUS WITH BATTERY INTERMITTENT SHORT DETECTION

(71) Applicant: Samsung Electronics Co., Ltd., Suwon-si (KR)

(72) Inventors: Sagar BHARATHRAJ, Karnataka (IN); Shashishekara Parampalli ADIGA, Karnataka (IN)

(73) Assignee: Samsung Electronics Co., Ltd., Suwon-si (KR)

(21) Appl. No.: 18/766,999

(22) Filed: Jul. 9, 2024

(30) Foreign Application Priority Data
Jul. 11, 2023 (IN) 202341046643
Apr. 3, 2024 (KR) 10-2024-0045183

(51) Int. Cl. G01R 31/3842; G01R 31/367

(52) U.S. Cl. CPC G01R 31/3842; G01R 31/367

(57) ABSTRACT

A processor-implemented method including generating a voltage slope based on monitored cell voltage and current data of a battery, the cell voltage and current data being taken during a charging window or discharging window of the battery, determining a change in a sign of the voltage slope by comparing the voltage slope with a reference voltage slope of a reference battery, determining, based on the change in the sign of the voltage slope, a deviation in a magnitude of the voltage slope by comparing the magnitude of the voltage slope with a preset magnitude of the reference voltage slope, and detecting an intermittent short in the battery based on a determination that a deviation in the magnitude of the voltage slope is greater than a preset threshold value.

### CROSS-REFERENCE TO RELATED APPLICATIONS

This application claims the benefit under 35 USC § 119 (a) of Indian patent application No. 202341046643 filed on Jul. 11, 2023, in the Indian Patent Office, and Korean Patent Application No. 10-2024-0045183 filed on Apr. 3, 2024, in the Korean Intellectual Property Office, the entire disclosures of which are incorporated herein by reference for all purposes.

### BACKGROUND

### 1. Field

The examples relate to a method and device with battery intermittent short detection.

### 2. Description of Related Art

With the increasing development of small and light portable electronic devices, rechargeable batteries are generally used as a power supply device for the operation of these and other types of devices. The rechargeable batteries are chargeable and dischargeable batteries, unlike primary batteries that cannot be charged. A rechargeable battery is used in a portable small electronic device, such as a portable phone or a notebook computer, or is widely used as a power source for driving a motor of a power tool, a vehicle, and the like. An internal part of the rechargeable battery may be formed of a positive electrode, a negative electrode, a separation film, an electrolyte, and the like, and a case may be formed of a metal plate or a pouch.

When a rechargeable battery has high energy density, it may become a safety issue, such as thermal runaway. In a representative example, in a case where the positive electrode and the negative electrode inside the rechargeable battery are shorted, then the rechargeable battery gets overheated. This type of short is called an internal short. In particular, when the rechargeable battery is being charged using an external power source, a short circuit (i.e., an internal short) may occur unintentionally due to an electrical contact between the positive electrode and the negative electrode of the rechargeable battery. In short circuit conditions, a resistance of the electrical contact between the positive electrode and the negative electrode of the rechargeable battery is called a short resistance Rₛₕ. A higher value of Rₛₕ permits a low amount of current to flow through the rechargeable battery, whereas a lower value of Rₛₕ permits a high amount of current to flow through the rechargeable battery. Thus, for the lower value of Rₛₕ, a large amount of thermal energy is released because of the high amount of current flowing between the positive electrode and the negative electrode. Further, the short circuit may cause additional chain reactions, like electrolyte decomposition, and may result in the loss of active material. As a result, the temperature of the rechargeable battery may be increased. Therefore, the short circuit may result in a rapid discharge of battery power, causing excessive heat buildup and may potentially lead to damage, failure, or even a fire in the rechargeable battery.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including generating a voltage slope based on monitored cell voltage and current data of a battery, the cell voltage and current data being taken during a charging window or discharging window of the battery, determining a change in a sign of the voltage slope by comparing the voltage slope with a reference voltage slope of a reference battery, determining, based on the change in the sign of the voltage slope, a deviation in a magnitude of the voltage slope by comparing the magnitude of the voltage slope with a preset magnitude of the reference voltage slope, and detecting an intermittent short in the battery based on a determination that a deviation in the magnitude of the voltage slope is greater than a preset threshold value.

The reference battery may correspond to a healthy battery including the reference voltage slope and the preset magnitude of the reference voltage slope during a preset constant charging or discharging window.

The method may include estimating, using an Electrochemical-Thermal (ECT) model, a severity of the detected intermittent short based on the deviation in the magnitude of the voltage slope with respect to the preset magnitude of the reference voltage slope of the reference battery under a similar reference condition.

The reference condition may correspond to an operating condition under which a temperature profile and a current profile of the battery are the same as a reference temperature profile and a reference current profile of the reference battery.

The ECT model may be a model that uses one or more of a Butler-Volmer equation, an Eyring equation, a Nernst equation, and a Tafel equation.

The method may include detecting a subsequent change in the sign of the voltage slope upon detecting the intermittent short in the battery and estimating a duration of the intermittent short in the battery based on a detection of the subsequent change in the sign of the voltage slope.

The method may include generating an alert if the estimated duration of the intermittent short is greater than a threshold duration.

The battery may be a rechargeable lithium-ion (Li-ion) battery.

The method may include intermittently monitoring the battery to obtain the cell voltage and current data.

In a general aspect, here is provided an electronic device including a battery, a battery manager communicatively coupled with the battery, one or more processors configured to execute instructions, the one or more processors being associated with the battery manager, and a memory storing the instructions, and an execution of the instructions configures the processor to generate a voltage slope based on cell voltage and current data of the battery taken by the battery manager during a charging window or discharging window of the battery, determine a change in a sign of the voltage slope by comparing the voltage slope with a reference voltage slope of a reference battery, determine, based on the change in the sign of the voltage slope, a deviation in a magnitude of the voltage slope by comparing the magnitude of the voltage slope with a preset magnitude of the reference voltage slope, and detect an intermittent short in the battery based on a determination that a deviation in the magnitude of the voltage slope is greater than a preset threshold value.

The reference battery may correspond to a healthy battery including the reference voltage slope and the preset magnitude of the reference voltage slope during a preset constant charging or discharging window.

The one or more processors may be configured to estimate, using an Electrochemical-Thermal (ECT) model, a severity of the detected intermittent short based on the deviation in the magnitude of the voltage slope with respect to the preset magnitude of the reference voltage slope of the reference battery under a similar reference condition.

The ECT model may be a model that uses one or more of a Butler-Volmer equation, an Eyring equation, a Nernst equation, and a Tafel equation.

The reference condition may correspond to an operating condition under which a temperature profile and a current profile of the battery are the same as a reference temperature profile and a reference current profile of the reference battery.

The one or more processors may be further configured to detect a subsequent change in the sign of the voltage slope upon detecting the intermittent short in the battery and estimate a duration of the intermittent short in the battery based on a detection of the subsequent change in the sign of the voltage slope.

The electronic device may include a display, and the one or more processors may be configured to control the display to display an alert if the estimated duration of the intermittent short is greater than a threshold duration.

The battery may be a rechargeable lithium-ion (Li-ion) battery.

The one or more processors may be further configured to control the battery manager to periodically monitor the battery to obtain the cell voltage and current data.

In a general aspect, here is provided a processor-implemented method including comparing a voltage slope, the voltage slope being based on monitored cell voltage and current data of a battery, with a reference voltage slope of a reference battery, comparing a magnitude of the voltage slope with a preset magnitude of the reference voltage slope to determine a deviation in a magnitude of the voltage slope, and determining an occurrence of an intermittent short in the battery based on a determination that a deviation in the magnitude of the voltage slope is greater than a preset threshold value.

The method may include intermittently measuring the cell voltage and current data of the battery during a charging window or discharging window of the battery.

Other features and aspects will be apparent from the following detailed description, the drawings, and the claims.

### BRIEF DESCRIPTION OF THE DRAWINGS

FIG. 1 illustrates an example electronic device for detecting and estimating an intermittent short in a battery, according to one or more embodiments.

FIG. 2 illustrates an example method of detecting and estimating an intermittent short in a battery, according to one or more embodiments.

FIG. 3 illustrates a detection of an intermittent short within a battery.

FIG. 4A illustrates an example change in a sign of a voltage slope during a charging window of a battery, according to one or more embodiments.

FIG. 4B illustrates an example change in a sign of a voltage slope during a charging window and a discharging window of a battery, according to one or more embodiments.

FIG. 5 illustrates an example rate of change in a voltage level of a battery with respect to a short resistance of the battery, according to one or more embodiments.

FIG. 6 illustrates an example effect of a charge rate on a rate of change in a voltage level of a battery, according to one or more embodiments.

FIG. 7A illustrates an example effect of temperature on a rate of change in a voltage level of a battery, according to one or more embodiments.

FIG. 7B illustrates an example effect of a state of charge (SOC) on a rate of change in a voltage level of a battery, according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience+−.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

As used in connection with various example embodiments of the disclosure, any use of the terms “module” or “unit” means hardware and/or processing hardware configured to implement software and/or firmware to configure such processing hardware to perform corresponding operations, and may interchangeably be used with other terms, for example, “logic,” “logic block,” “part,” or “circuitry”. As one non-limiting example, an application-predetermined integrated circuit (ASIC) may be referred to as an application-predetermined integrated module. As another non-limiting example, a field-programmable gate array (FPGA) or an application-specific integrated circuit (ASIC) may be respectively referred to as a field-programmable gate unit or an application-specific integrated unit. In a non-limiting example, such software may include components such as software components, object-oriented software components, class components, and may include processor task components, processes, functions, attributes, procedures, subroutines, segments of the software. Software may further include program code, drivers, firmware, microcode, circuits, data, database, data structures, tables, arrays, and variables. In another non-limiting example, such software may be executed by one or more central processing units (CPUs) of an electronic device or secure multimedia card.

Techniques for detecting the state of a short circuit in a rechargeable battery in advance and preventing the short circuit are currently deployed in some devices. However, the detection of the state of the short circuit is very challenging at an early life stage of the battery, as signatures for determining the short circuit at the early life stage are very weak. When the short circuit is continuously present in the rechargeable battery, then such a short circuit is called a persistent short. Further, when a short circuit is temporarily present in the rechargeable battery, then such a short circuit is known as an intermittent short. Although the intermittent short is not initially dangerous, if the intermittent short is left unaddressed for a sufficient amount of time, the intermittent short may evolve and develop into potentially dangerous structures such as dendrites forming which may cause catastrophic incidents like thermal runaway.

Therefore, devices and method for detecting an intermittent short and a duration of the intermittent short within a rechargeable battery is desired to prevent such catastrophic incidents.

The terms “rechargeable battery” and “battery” are used interchangeably throughout the description without deviating or departing from the scope of the disclosure.

The terms “electronic device”, “device”, and “battery control device” are used interchangeably throughout the description without deviating or departing from the scope of the disclosure.

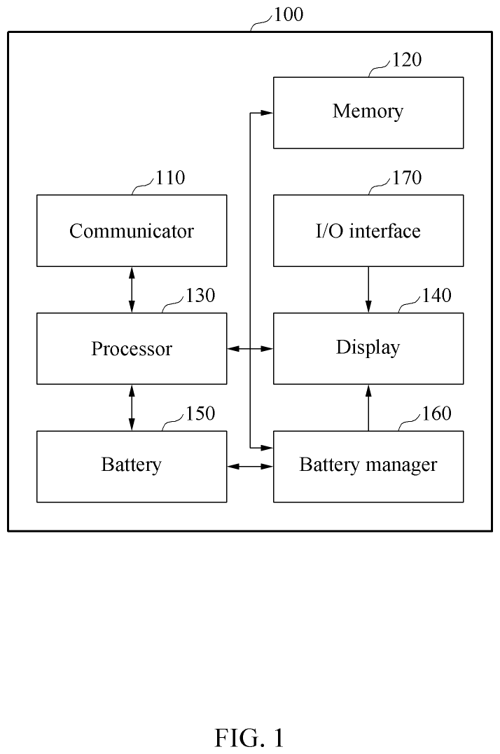

Hereinafter, a method and device for detecting and estimating an intermittent short in a battery according to an example of the disclosure will be described in detail with reference to FIG. 1 to FIG. 7B.

FIG. 1 illustrates an example electronic device for detecting and estimating an intermittent short in a battery, according to one or more embodiments Referring to FIG. 1, in a non-limiting example, an electronic device 100 may include a communicator 110, a memory 120, a processor 130, a display 140, a battery 150, a battery manager 160, and an input/output (I/O) interface 170. In an example, the electronic device 100 may include, but is not limited to, a mobile phone, a smartphone, a tablet computer, a handheld device, a laptop, a wearable computing device, an Internet of Things (IoT) based device, a digital camera, or a device or apparatus having a rechargeable battery.

The communicator 110 may be configured for internal communication between internal units and external devices via one or more networks.

The memory 120 may include computer-readable instructions. The processor 130 may be configured to execute computer-readable instructions, such as those stored in the memory 120, and through execution of the computer-readable instructions, the processor 130 is configured to perform one or more, or any combination, of the operations and/or methods described herein. The memory 120 may be a volatile or nonvolatile memory. Examples of such non-volatile storage elements may include a magnetic hard disk, an optical disc, a floppy disk, a solid-state drive (SSD), Non-Volatile Memory Express (NVMe), Non-volatile Dual In-line Memory Module (NVDIMM), Non-Volatile Random Access Memory (NVRAM), Non-volatile SRAM (NVSRAM), a flash memory, or forms of an electrically programmable memory (EPROM) or electrically erasable and programmable (EEPROM) memory. In addition, the memory 120 may, in some examples, be considered a non-transitory storage medium. The term “non-transitory” may indicate that the storage medium is not embodied in a carrier wave or a propagated signal. However, the term “non-transitory” should not be interpreted that the memory 120 is non-movable. In some examples, the memory 120 may be configured to store a larger amount of information. In certain examples, a non-transitory storage medium may store data that may change over time (e.g., in a random-access memory (RAM) or cache).

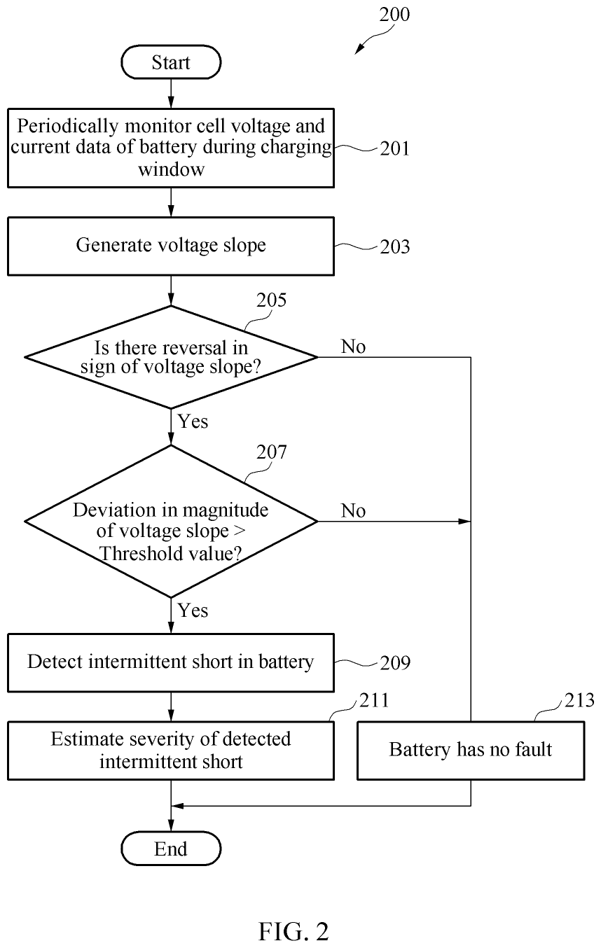

The processor 130 may further execute programs, and/or may control the electronic apparatus 100 to perform, in an example, battery management and intermittent short detection (e.g., the method of FIG. 2), and may include any one or a combination of two or more of, for example, a central processing unit (CPU), a graphic processing unit (GPU), a neural processing unit (NPU) and tensor processing units (TPUs), but is not limited to the above-described examples. The processor 130 may be operatively coupled to the memory 120 and the battery manager 160 for processing, executing, or performing a series of operations. The processor 130 may include specialized processing units such as an integrated system (bus) controller, a memory management control unit, a floating point unit, a graphics processing unit, a digital signal processing unit, etc. In an example. The processor 130 may be one or more general processors, digital signal processors, application-specific integrated circuits, field-programmable gate arrays, servers, networks, digital circuits, analog circuits, combinations thereof, or other now known or later developed devices for analyzing and processing data. The processor 130 may execute one or more instructions, such as code generated manually (i.e., programmed) to perform one or more operations disclosed herein.

The display 140 is also referred to as a display screen or a graphical user interface. The display 140 may be any output device configured to visually present information to a user of the electronic device 100. The primary purpose of the display 140 is to render visual content and provide a user interface for interacting with the electronic device 100.

The battery manager 160 is coupled to the processor 130 and the battery 150. In an example, the battery manager 160 may be an electronic module configured to manage the battery 150, for example, a rechargeable battery (a cell or a battery pack). The battery manager 160 may be configured to manage charging and discharging of the battery 150 and provide notifications indicating the state of the battery 150 on the display 140. The battery manager 160 may provide critical safeguards to protect the battery 150 from damage. The battery 150 may be a rechargeable battery. An example of the rechargeable battery may be a lithium-ion battery (LIB). The term “healthy battery” is used herein to illustrate a condition of the battery 150 when the battery 150 is manufactured and used for the first time within the electronic device 100. The health of the battery 150 may degrade after a certain amount and/or type of usage of the battery 150.

The battery manager 160 may be further configured to periodically, or intermittently, monitor a cell voltage and current data of the battery 150 during a charging window or a discharging window. In an example, when a user connects a charger to the electronic device 100, the battery 150 may start storing charge and electrical energy. During the charging window, the battery manager 160 may monitor charging profile information of the battery 150 and store the monitored charging profile information of the battery 150. The charging profile information of the battery 150 may be monitored each time when the charging operation is initiated.

The processor 130 may be configured to generate a voltage slope based on the periodically monitored cell voltage and current data of the battery 150. The voltage slope refers to the rate of change in a voltage level of the battery 150. The processor 130 may be further configured to determine a change in a sign of the voltage slope by comparing the voltage slope with a reference voltage slope of a healthy battery. The reference voltage slope and a preset magnitude of the reference voltage slope correspond to a respective voltage slope and a magnitude of the voltage slope of the healthy battery during a preset constant charging or discharging window. In an example, the processor 130 may be configured to determine, based on the change in the sign of the voltage slope, a deviation in a magnitude of the voltage slope by comparing the magnitude of the voltage slope with a preset magnitude of the reference voltage slope. Additionally, the processor 130 may be configured to determine whether the deviation in the magnitude of the voltage slope is greater than a preset threshold value and detect the intermittent short in the battery 150 when it is determined that the deviation in the magnitude of the voltage slope is greater than the preset threshold value.

The I/O interface 170 refers to hardware or software components that enable the electronic device 100 to receive input from a keyboard, mouse, or touchscreen, and provide output to the display 140. The I/O interface 170 may also be used to provide the user a way to interact with the electronic device 100. The I/O interface 170 may also enable data communication between the electronic device 100 and any other device(s) or system(s).

Although FIG. 1 shows the hardware elements of the electronic device 100, it is to be understood that other examples are not limited thereto. In an example, the electronic device 100 may include fewer or more elements. Further, the labels or names of the elements are used only for illustrative purposes and do not limit the scope of the disclosure. One or more components may be combined together to perform the same or substantially similar functions for detecting and estimating an intermittent short in the battery 150 of the electronic device 100.

Hereinafter, a method according to the disclosure configured as above is described with reference to the drawings.

FIG. 2 illustrates an example method of detecting and estimating an intermittent short in a battery, according to one or more embodiments.

Referring to FIG. 2, in a non-limiting example, in operation 201, the processor 130 may control the battery manager 160 to periodically monitor a cell voltage and current data of the battery 150 during a charging window or a discharging window of the battery 150.

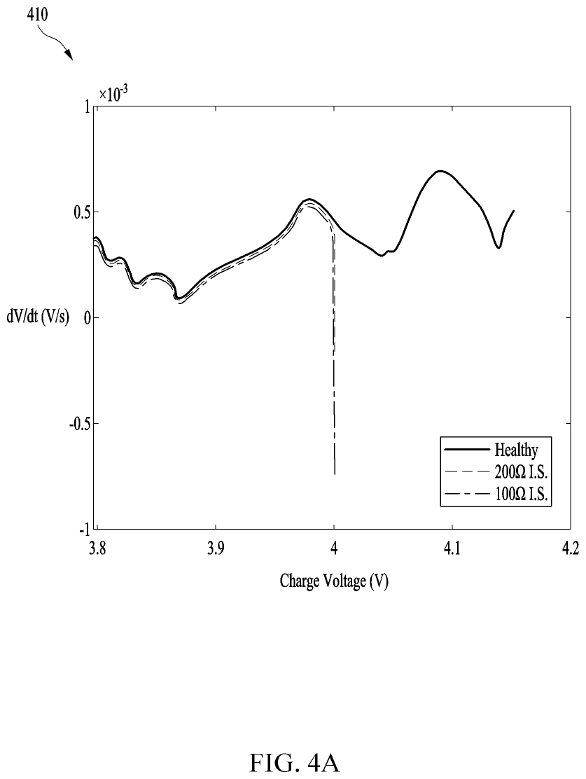

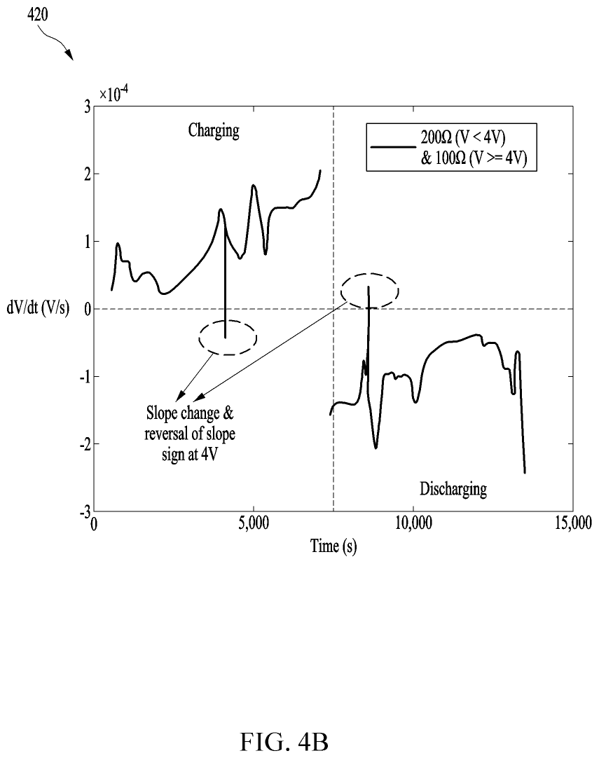

In operation 203, the processor 130 may generate a voltage slope based on the periodically monitored cell voltage and current data of the battery 150. Exemplary graphs depicting the voltage slope are shown in FIGS. 4A and 4B. A detailed description of FIGS. 4A and 4B is provided below.

In operation 205, the processor 130 may determine a change in a sign of the voltage slope by comparing the voltage slope with a reference voltage slope of a healthy battery. The healthy battery may also be referred to as a reference battery without any deviation from the scope of the disclosure. In an example, the processor 130 may determine whether there is a reversal in the sign of the voltage slope.

In case the result of the determination in operation 205 indicates that there is no reversal in the sign of the voltage slope, then the processor 130 may proceed to operation 213 to determine that the battery 150 has no fault or an intermittent short is not present within the battery 150.

In a case where the result of the determination in operation 205 indicates that there is a reversal in the sign of the voltage slope, then the processor 130 may determine, based on the change in the sign of the voltage slope, a deviation in the magnitude of the voltage slope by comparing the magnitude of the voltage slope with a preset magnitude of a reference voltage slope, and may determine whether the deviation in the magnitude of the voltage slope is greater than a threshold value of 7.5×10⁻³ (i.e., three times the mean value of the voltage slope), for example, in operation 207.

In a case where the result of the determination in operation 207 indicates that the deviation in the magnitude of the voltage slope is less than or equal to the threshold value, then the processor 130 may proceed to operation 213 to determine that the battery 150 has no fault or an intermittent short is not present within the battery 150.

In a case where the result of the determination in operation 207 indicates that the deviation in the magnitude of the voltage slope is greater than the threshold value, then the processor 130 may detect an intermittent short in the battery 150.

In operation 211, the processor 130 may estimate a severity of the detected intermittent short based on the deviation in the magnitude of the voltage slope with respect to the preset magnitude of the reference voltage slope of the healthy battery under a similar reference condition.

In an example, the processor 130 may estimate the severity of the detected intermittent short using an Electrochemical-Thermal (ECT) model. The ECT model may correspond to a model such as, but not limited to, a Butler-Volmer equation, an Eyring equation, a Nernst equation, or a Tafel equation. The reference condition corresponds to an operating condition under which a temperature profile and a current profile of the battery 150 are the same as a reference temperature profile and a reference current profile of the healthy battery. The current profile of the battery 150 may include one or more parameters including a charging rate and a state of charge (SOC).

In an example, the processor 130 may also detect a subsequent change in the sign of the voltage slope upon detecting the intermittent short in the battery 150. Thereafter, the processor 130 may estimate the duration of the intermittent short in the battery 150 based on the detection of the subsequent change in the sign of the voltage slope. In a case where the estimated duration of the intermittent short is greater than a threshold duration, then the processor 130 may control the display 140 to display an alert to the user of the electronic device. The alert may also be provided in the form of a visual indicator, such as a flashing light, or an audible indicator, such as a beeping sound. The alert may be accompanied by a message that instructs the user of the electronic device 100 to perform one or more actions, for example, but not limited to, disconnecting the battery 150 from the electronic device 100, shutting down the electronic device 100, visiting a service center to for a replacement of the battery 150, and the like.

The various actions, acts, blocks, operations, or the like in the method may be performed in the order presented, in a different order, or simultaneously. Further, in some examples, some of the actions, acts, blocks, operations, or the like may be omitted, added, modified, skipped, or the like without departing from the scope of the invention.

Accordingly, in an example, an intermittent short may be detected, and the severity of the intermittent short may be estimated to provide an alert to the user of the electronic device 100 in advance.

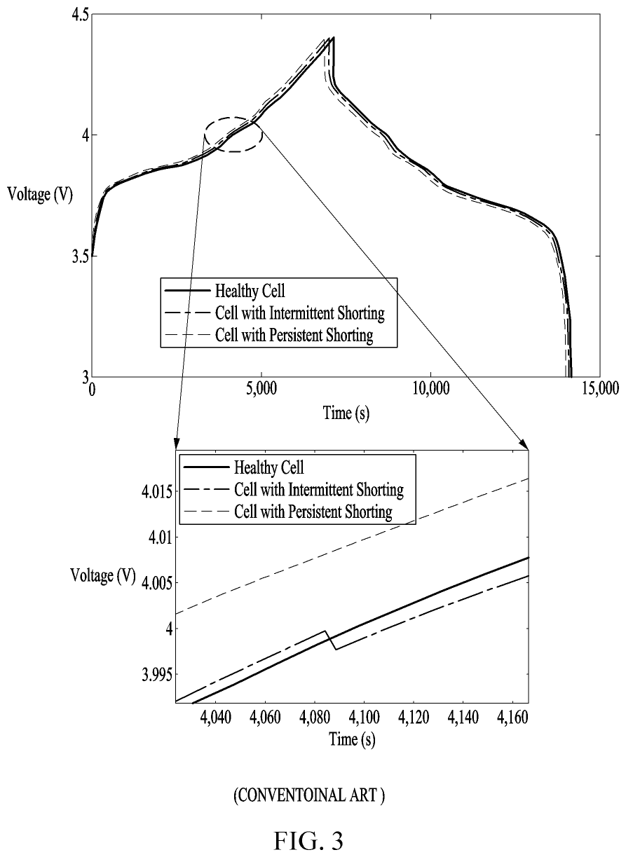

FIG. 3 illustrates a detection of an intermittent short within a battery.

As described above, an internal short in a battery (e.g., such as the battery 150) may occur due to various reasons such as an electrical contact between a positive electrode and a negative electrode of the battery. The internal short may be a persistent or regular short (RS) and an intermittent/irregular short (IS). In both short circuit conditions, a short resistance Ran is generated between the positive electrode and the negative electrode of the battery. A change in the voltage charge and discharge characteristics of the battery may be observed during the RS or the IS in the battery. However, the observation of the change in the voltage charge and discharge characteristics is difficult to identify only by visually analyzing the voltage charge and discharge characteristics of the battery.

Referring to FIG. 3, the voltage charge and discharge characteristics of each of a healthy battery is illustrated including a battery with the IS, and a battery with the RS Typically, a short is generated when a cell voltage is greater than 4 volts (V). Referring to FIG. 3, the magnitudes of electrode voltages in the healthy battery, the battery with the IS, and the battery with the RS are 4V, may be too close to each other to be distinguished based on the visual analysis. Further, by scaling or zooming the voltage charge and discharge characteristic curve, the RS may be detected with the battery. However, the IS is typically difficult to detect within the battery.

However, based on the above-described reference condition and parameters such as the sign of the voltage slope, a processor (e.g., the processor 130) may detect an intermittent short in the battery by checking for a condition whether the deviation in the magnitude of the voltage slope is greater than the threshold value of 7.5×10⁻³ (i.e., three times the mean value of the voltage slope). Thus, in a case where an intermittent short is detected, the processor controls a display (e.g., the display 140), for example, to display an alert to the user or control one or more components of an electronic device (e.g., the electronic device 100), such as a flashlight or haptic sensors, to alert the user. The alert may help the user of the electronic device to perform one or more actions to prevent the electronic device from damage or any catastrophic incidents like thermal runaway.

FIG. 4A illustrates an example change in a sign of a voltage slope during a charging window of a battery, according to one or more embodiments.

Referring to FIG. 4A, in a non limiting example, graph 410 may depict a change in a sign of a voltage slope during a charging window of a battery 150.

FIG. 4B illustrates an example change in a sign of a voltage slope during a charging window and a discharging window of a battery, according to one or more embodiments.

Referring to FIG. 4B, in a non-limiting example, graph 420 may depict a change in a sign of a voltage slope during a charging window and a discharging window of a battery 150.

Referring to FIGS. 4A and 4B, the voltage slope of the battery 150 is represented as a dV/dt profile. The dV/dt profile helps in identifying a clear spike for the battery 150 with intermittent shorting. The dV/dt profile also changes the sign as a first indication of a short, and a magnitude of the dV/dt profile is related to Rxh. In addition, the dV/dt sign changes to negative during the charging window, and the other way around (i.e., from negative to positive) during the discharging window. In an example, the mean value of the voltage slope for a healthy battery at a temperature of 293K and a charging rate of 0.5 is 0.25×10⁻³. The mean value of the voltage slope varies with respect to a change in Rₛₕ. Table 1 below illustrates a change in the mean value of the voltage slope with respect to the change in Rₛₕ.

TABLE 1

| Rₛₕ (Ω) | dV/dt (V/s) |
|---|---|
| 200 | 0.0010 (4 times mean) |
| 100 | 0.0016 (6) |
| 50 | 0.0028 (11) |
| 25 | 0.0052 (21) |
| 12 | 0.0104 (42) |
| 6 | 0.0209 (85) |

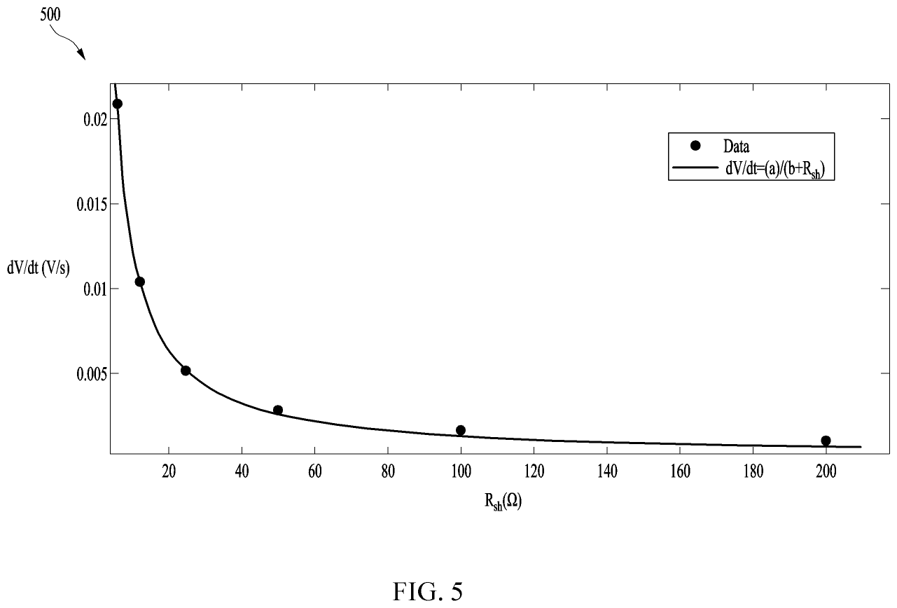

FIG. 5 illustrates an example rate of change in a voltage level of a battery with respect to a short resistance of the battery, according to one or more embodiments. Referring to FIG. 5, in a non-limiting example, in graph 500, the rate of change in the voltage level of the battery 150 is illustrated as being inversely proportional to Rₛₕ of the battery 150. An estimation of a relationship between the rate of change in the voltage level of the battery 150 and Ron of the battery 150 may be given as shown below in Equation 4. Equation 4 illustrates a rational scaling between intermittent short resistance and the deviation in the voltage slope. A detailed description related to the derivation of Equation 4 is provided below.

Specifically, in a case where there is no load on the battery 150, a voltage across the electrodes of the battery 150 is equal to an open circuit voltage of the battery 150. Further, in a case where a load of resistance R is applied across the electrodes of the battery 150, current I flows through the resistance R. In this case, the voltage across the electrodes of the battery 150 may be given by Equation 1.

$${V}_{c e l l} = OCV - IR \qquad Equation 1$$

Further, a derivative of Equation 1 may be given as Equation 2.

$$\frac{d {V}_{c e l l}}{d t} = \frac{dOCV}{d t} - \frac{d ( IR )}{d t} \qquad Equation 2$$

Further, in case of an internal short, the current I may be expressed as Equation 3.

$$I = {I}_{battery} - {I}_{short} = {I}_{battery} - \frac{{V}_{cell}}{{R}_{s h}} \qquad Equation 3$$

In Equation 3, Iₛₕₒᵣₜ is a short circuit current, I_{battery} is the circuit current drawn by the load, and Rₛₕ is the short resistance.

Equation 4 may be derived by solving Equations 2 and 3 as shown below:

$$\frac{d {V}_{c e l l}}{d t} = \frac{dOCV}{d t} - R \frac{d ( {I}_{battery} )}{d t} + \frac{R}{{R}_{s h}} \frac{d ( {V}_{c e l l} )}{d t}$$

$$\frac{d {V}_{c e l l}}{d t} = \frac{\frac{dOCV}{d t} - R \frac{d ( {I}_{battery} )}{d t}}{( 1 - \frac{R}{{R}_{s h}} )}$$

Accordingly, the circuit current I_{battery} is almost constant, especially during CC charging

$$( \frac{d ( {I}_{b a t t e r y} )}{dt} = 0 ) .$$

$$\frac{d {V}_{c e l l}}{d t} = \frac{\frac{dOCV}{d t}}{( 1 - \frac{R}{{R}_{s h}} )} i . e \frac{d {V}_{c e l l}}{d t} α \frac{1}{( 1 - \frac{R}{{R}_{s h}} )} \qquad Equation 4$$

In particular, Equation 4 determines the relation between the rate of change in the voltage level of the battery 150 with respect to Rₛₕ of the battery 150.

Further, a derivative of Equation 4 may be given as Equation 5.

$$\frac{{d}^{2} {V}_{c e l l}}{d {t}^{2}} α \frac{R}{{R}_{s h}^{2}} \frac{d {R}_{s h}}{d t} \qquad Equation 5$$

Thus, when Rₛₕ decreases, the derivative as shown in Equation 5 becomes negative and vice versa, leading to a reversal of the sign of the voltage slope.

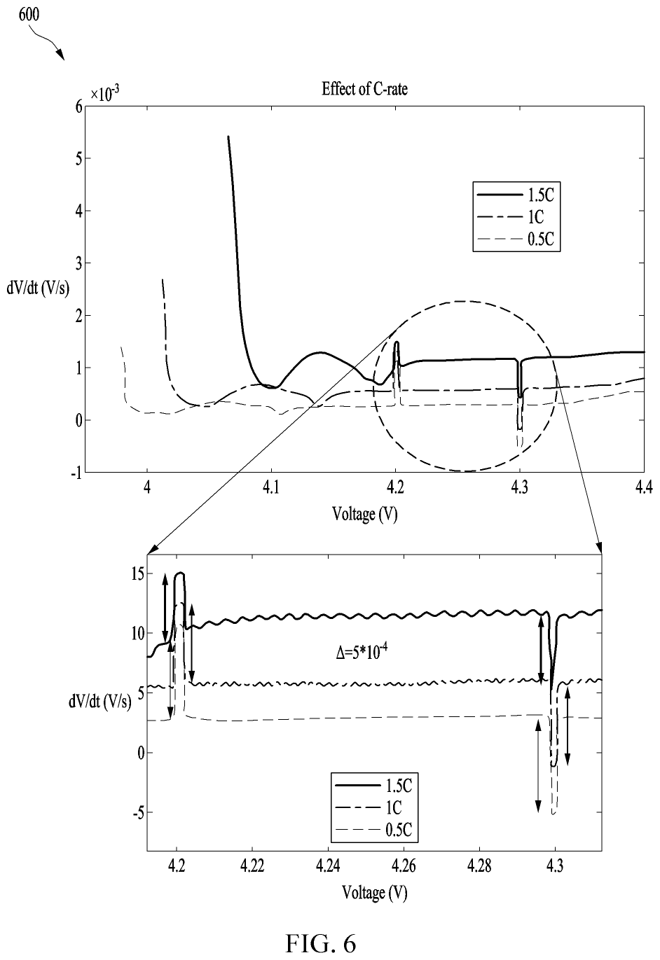

FIG. 6 illustrates an example effect of a charge rate on a rate of change in a voltage level of a battery, according to one or more embodiments. Referring to FIG. 6, in a non-limiting example, graph 600 illustrates a rate of change in the voltage level of the battery 150 at different charge rates. In an example, the rate of change in the voltage level of the battery 150 is determined at charge rates of 1C, 1.5C, and 0.5C. In an example, the charge rate of 1C fully charges or discharges the battery 150 in 1 hour. However, the charge rate of 0.5C fully charges or discharges the battery 150 in 2 hours.

Further, as an example, an internal short of Rₛₕ=5002 is triggered at 4.2 V and removed at 4.3 V. As a result, voltage spikes are generated due to the triggering and removal of the internal short at 4.2 V and 4.3 V. The generated voltage spikes may be seen in the graph 600 for each of the charge rates.

Referring to the zoomed-in plot view of FIG. 6, the magnitude of the change in the rate of the voltage level of the battery 150 is the same irrespective of the varying charge rate of the battery 150. Therefore, the rate of change in the voltage level due to a short circuit does not depend on the charge rate and depends only on the short severity/resistance Rₛₕ.

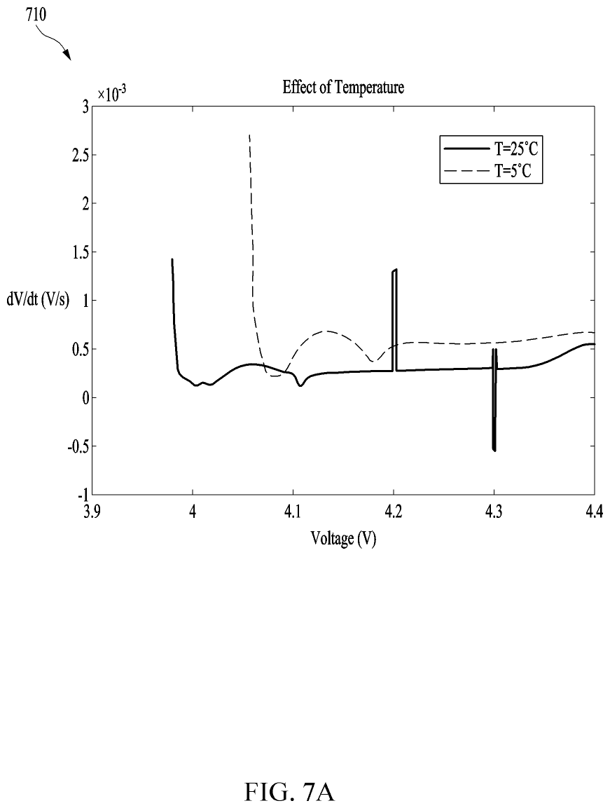

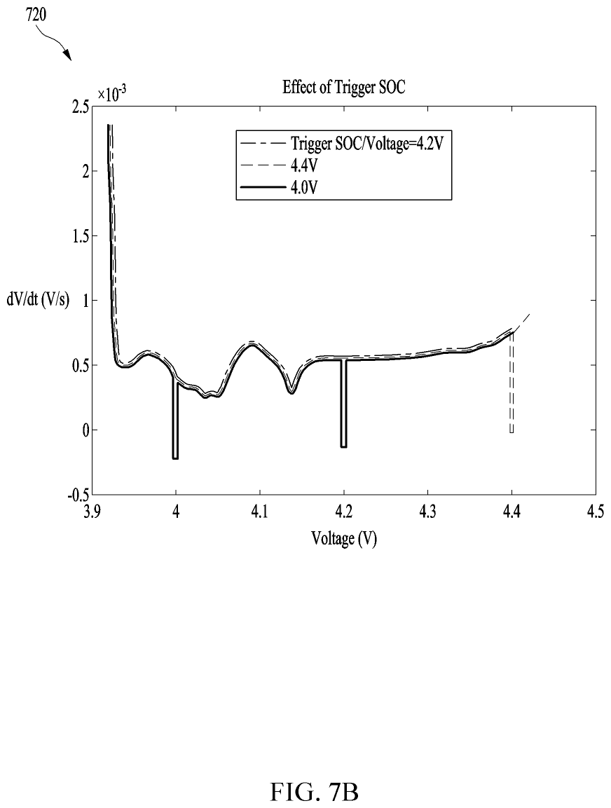

FIG. 7A illustrates an example effect of temperature on a rate of change in a voltage level of a battery, according to one or more embodiments. Referring to FIG. 7A, in a non-limiting example, graph 710 illustrates a rate of change in the voltage level of the battery 150 at different temperatures. In an example, the rate of change in the voltage level of the battery 150 is determined at the temperatures of 5° C. and 25° C. at the charge rate of 0.5C.

Further, as an example, the internal short of Rₛₕ=5002 is triggered at 4.2 V and removed at 4.3 V. As a result, the voltage spikes are generated due to the triggering and removal of the internal short at 4.2 V and 4.3 V. The generated voltage spikes may be seen in the graph 710 corresponding to each of the temperature values.

In addition, the magnitude of the change in the rate of the voltage level of the battery 150 is the same irrespective of the varying temperature value. Therefore, the rate of change in the voltage level due to the short circuit does not depend on the varying temperature value and depends only on the short severity/resistance Rₛₕ.

FIG. 7B illustrates an example effect of a state of charge (SOC) on a rate of change in a voltage level of a battery, according to one or more embodiments. Referring to FIG. 7B, in a non-limiting example, graph 720 illustrates a rate of change in the voltage level of the battery 150 with respect to the voltage level of the battery 150. Further, as an example, the internal short of Rₛₕ=5052 is triggered at different SOCs/voltages of 4.0 V, 4.2 V, and 4.4 V at the charge rate of 0.5C. As a result, as shown in FIG. 7B, the voltage spikes are generated at respective trigger points of 4.0 V, 4.2 V, and 4.4 V.

Also, as seen in FIG. 7B, the magnitudes of the voltage spikes are the same at each of the trigger points of 4.0 V, 4.2 V, and 4.4 V. Therefore, the rate of change in the voltage level due to the short circuit does not depend on the SOC of the battery 150 and depends only on the short severity/resistance Rₛₕ.

Accordingly, the rate of change in the voltage level due to the short circuit does not depend on any of the charge rate of the battery 150, the temperature of the battery 150, and the SOC of the battery 150. Thus, the rate of change in the voltage level of the battery 150 due to the short circuit only depends on Rₛₕ of the battery 150.

In an example, in method 200 and the electronic device 100, an intermittent short may be detected in a battery, thereby improving battery safety. Apart from detecting and accurately estimating an intermittent short, in an example, method 200 may determine a duration of the intermittent short using an alert that may be provided to the user to safeguard the battery 150 from being damaged.

In an example, an intermittent short may be detected using only device data of the electronic device 100 without requiring additional probes. Method 200 may, in an example, be easily integrated into Power Management Integrated Circuit (PMIC)/Battery Management System (BMS) without additional computational expenditure or special data. In an example, the method 200 may work at multiple stages/values of the constant current, which is usually the charging protocol and may be used as an additional protocol for detecting an intermittent short without additional computation/implementation cost.

The memory, processors, electronic device, electronic device 100, communicator 110, memory 120, processor 130, display 140, battery 150, battery manager 160, I/O interface 170 described herein and disclosed herein described with respect to FIGS. 1-7B are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-7B that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
generating a voltage slope based on monitored cell voltage and current data of a battery, the cell voltage and current data being taken during a charging window or discharging window of the battery;
determining a change in a sign of the voltage slope by comparing the voltage slope with a reference voltage slope of a reference battery;
determining, based on the change in the sign of the voltage slope, a deviation in a magnitude of the voltage slope by comparing the magnitude of the voltage slope with a preset magnitude of the reference voltage slope; and
detecting an intermittent short in the battery based on a determination that a deviation in the magnitude of the voltage slope is greater than a preset threshold value.

2. The method of claim 1, wherein the reference battery corresponds to a healthy battery including the reference voltage slope and the preset magnitude of the reference voltage slope during a preset constant charging or discharging window.

3. The method of claim 1, further comprising:
estimating, using an Electrochemical-Thermal (ECT) model, a severity of the detected intermittent short based on the deviation in the magnitude of the voltage slope with respect to the preset magnitude of the reference voltage slope of the reference battery under a similar reference condition.

4. The method of claim 3, wherein the reference condition corresponds to an operating condition under which a temperature profile and a current profile of the battery are the same as a reference temperature profile and a reference current profile of the reference battery.

5. The method of claim 4, wherein the ECT model is a model that uses one or more of a Butler-Volmer equation, an Eyring equation, a Nernst equation, and a Tafel equation.

6. The method of claim 1, further comprising:
detecting a subsequent change in the sign of the voltage slope upon detecting the intermittent short in the battery; and
estimating a duration of the intermittent short in the battery based on a detection of the subsequent change in the sign of the voltage slope.

7. The method of claim 6, further comprising:
generating an alert if the estimated duration of the intermittent short is greater than a threshold duration.

8. The method of claim 1, wherein the battery comprises a rechargeable lithium-ion (Li-ion) battery.

9. The method of claim 1, further comprising:
intermittently monitoring the battery to obtain the cell voltage and current data.

10. An electronic device, comprising:
a battery;
a battery manager communicatively coupled with the battery;
one or more processors configured to execute instructions, the one or more processors being associated with the battery manager; and
a memory storing the instructions, wherein execution of the instructions configures the processor to: generate a voltage slope based on cell voltage and current data of the battery taken by the battery manager during a charging window or discharging window of the battery;
determine a change in a sign of the voltage slope by comparing the voltage slope with a reference voltage slope of a reference battery;
determine, based on the change in the sign of the voltage slope, a deviation in a magnitude of the voltage slope by comparing the magnitude of the voltage slope with a preset magnitude of the reference voltage slope; and
detect an intermittent short in the battery based on a determination that a deviation in the magnitude of the voltage slope is greater than a preset threshold value.

11. The electronic device of claim 10, wherein the reference battery corresponds to a healthy battery including the reference voltage slope and the preset magnitude of the reference voltage slope during a preset constant charging or discharging window.

12. The electronic device of claim 10, wherein the one or more processors are configured to estimate, using an Electrochemical-Thermal (ECT) model, a severity of the detected intermittent short based on the deviation in the magnitude of the voltage slope with respect to the preset magnitude of the reference voltage slope of the reference battery under a similar reference condition.

13. The electronic device of claim 12, wherein the ECT model is a model that uses one or more of a Butler-Volmer equation, an Eyring equation, a Nernst equation, and a Tafel equation.

14. The electronic device of claim 12, wherein the reference condition corresponds to an operating condition under which a temperature profile and a current profile of the battery are the same as a reference temperature profile and a reference current profile of the reference battery.

15. The electronic device of claim 10, wherein the one or more processors are configured to:
detect a subsequent change in the sign of the voltage slope upon detecting the intermittent short in the battery; and
estimate a duration of the intermittent short in the battery based on a detection of the subsequent change in the sign of the voltage slope.

16. The electronic device of claim 15, further comprising:
a display, wherein the one or more processors are configured to control the display to display an alert if the estimated duration of the intermittent short is greater than a threshold duration.

17. The electronic device of claim 10, wherein the battery comprises a rechargeable lithium-ion (Li-ion) battery.

18. The electronic device of claim 10, wherein the one or more processors are further configured to:
control the battery manager to periodically monitor the battery to obtain the cell voltage and current data.

19. A processor-implemented method, the method comprising:
comparing a voltage slope, the voltage slope being based on monitored cell voltage and current data of a battery, with a reference voltage slope of a reference battery;
comparing a magnitude of the voltage slope with a preset magnitude of the reference voltage slope to determine a deviation in a magnitude of the voltage slope; and
determining an occurrence of an intermittent short in the battery based on a determination that a deviation in the magnitude of the voltage slope is greater than a preset threshold value.

20. The method of claim 19, further comprising:
intermittently measuring the cell voltage and current data of the battery during a charging window or discharging window of the battery.
